(19) United States
(12) Patent Application Publication
(10) Pub. No.: US 2005/0018862 A1
(43) Pub. Date: Jan. 27, 2005

(54) Digital signal processing system and method for a telephony interface apparatus

(76) Inventor: Michael John Amiel Fisher, Cremorne (AU)

Correspondence Address: SEYFARTH SHAW, 55 EAST MONROE STREET, SUITE 4200, CHICAGO, IL, 60603-5803, US

(21) Appl. No.: 10/481,194

(22) PCT Filed: Jun. 28, 2002
(86) PCT No.: PCT/AU02/00852

(30) Foreign Application Priority Data
Jun. 29, 2001 (AU) PR6042

(51) Int. Cl. H03G 5/00

(52) U.S. Cl. 381/98

(57) ABSTRACT

A signal processing method including the steps of: receiving a first audio signal; detecting the presence of one or more shrieks within an audible frequency range of said audio signal; creating one or more filters to selectively attenuate the respective one or more shrieks within the audible frequency range; filtering the audio signal using the one or more filters; and transmitting the filtered audio signal to an audio telephone device.

### FIELD OF THE INVENTION

The present invention relates generally to digital signal processing systems and methods for a telephony interface apparatus. More particularly, the invention relates to digital telephony apparatus interposed between a headset, handset or similar arrangement of electro-acoustic transducers and a telephony device for suppressing audio telephony signals which may be harmful to the human ear.

### BACKGROUND

Occasionally, intense, unwanted signals accidentally occur within the telephone network. These signals are variously called acoustic shocks, audio shocks, acoustic shrieks, or high-pitched tones and will be referred to herein as shrieks or narrow-band signals. The exact source of an individual acoustic shock is usually unknown, but various sources are possible, such as alarm signals, signalling tones, or feedback oscillation.

Although these narrow-band noises can affect anyone, people using a regular hand-held telephone can quickly move the phone away from their ear, thus limiting their sound exposure to a fraction of a second.

Call-centre operators, however, usually use a headset, which takes considerably longer to remove from the ear were an intense sound to occur. They thus receive a greater noise exposure than for people using hand-held phones. The problem may be exacerbated if call centres are so noisy that the operators need to have the volume controls on their telephones turned up higher than would be necessary in a quieter place.

Unexpected high-level sounds have been reported to cause a variety of symptoms. Symptoms that have been reported during the exposure include discomfort and pain.

Current methods to protect against acoustic shock involve limiting the voltage delivered to the headsets so that the sound level delivered to the ear is also limited in some way. Two forms of limiting are used. The first, peak clipping, acts instantaneously, but simultaneously creates distortion. The second is called compression limiting, and involves the rapid reduction of the gain of the device. Compression limiting creates less distortion, but there is a conflict between the need to reduce the gain slowly (to avoid distortion) and the need to reduce the gain quickly (to provide rapid protection from high level signals on the telephone line).

One problem with current forms of limiting is that the devices limit the voltage delivered to the headset in a frequency-independent manner. Because headsets produce different sound levels at different frequencies for the same input voltage, the limiting produced at the eardrum depends on the characteristics of the headset. In particular, headsets of the type used in telephony are known to emphasise high-frequency sounds relative to low-frequency sounds. Conventional limiting systems thus limit low-frequency sounds to lower levels than they limit high-frequency sounds. As acoustic shocks are believed to be caused by high-frequency sounds, the standard solution is not well matched to the problem.

An additional (and greater) problem for conventional limiting systems is that there is a severe compromise between selecting a limiting level that is low enough to protect against acoustic shock, but high enough to allow good intelligibility when phone operators listen in noisy environments to speech from callers. The literature on the acoustic startle response (which is believed to underlie the acoustic shock problem) suggests that even very low volume levels can lead to a startle if the sound (such as a high-pitched tone) is perceived by the operator to be dangerous. It is believed that with current methods of limiting it is not possible to choose any limiting level that simultaneously protects against acoustic shock and achieves good intelligibility.

Prior art amplification systems avoid acoustic feedback by selectively reducing the gain of the devices in the chain that are causing the feedback oscillation. The acoustic shock problem is different, in that the headset and limiting amplifier are not necessarily part of the chain of devices that are causing the feedback.

Prior art acoustic shock protection devices are generally analogue in nature and suffer from problems such as those mentioned above. Such devices also offer limited display and controllability of device settings. Also, such devices are usually configured to operate only with a particular headset and are not suited for or capable of accommodating headsets having different frequency response characteristics.

### SUMMARY OF THE INVENTION

In a first aspect the present invention provides a method of controlling the exposure of a listener to narrow-band signals in an audio signal including the steps of:
periodically analysing the signal to determine the signal levels in particular frequency regions;
detecting a narrow-band signal based on whether the ratio of the signal level in a particular frequency region to the signal level in nearby higher and lower frequency regions exceeds a pre-determined threshold; and
in response to detection of a narrow-band signal, controlling the exposure of the listener to the detected narrow-band signal.

In a second aspect of the present invention the present invention provides an apparatus for controlling the exposure of a listener to narrow-band signals in an audio signal including:
analysing means to periodically analyse the signal to determine the signal levels in particular frequency regions;
detection means arranged to detect a narrow-band signal based on whether the ratio of the signal level in a particular frequency region to the signal level in nearby higher and lower frequency regions exceeds a pre-determined threshold; and
controlling means arranged to control the exposure of the listener in response to detection of a narrow-band signal.

One embodiment of the invention relates to an amplifying device adapted to detect the presence of one or more high-pitched narrow bandwidth signals within audio telephony signals, in isolation or in the presence of speech signals, and perform rapid, selective attenuation of the one or more narrow bandwidth signals to levels lower than those that occur at the same frequencies when speech is received in the absence of such high-pitched signals.

Advantages of this embodiment include:
1. The greatly reduced level of high-pitched narrow-band signals makes them less dangerous to operators;
2. The effectiveness of the device can be demonstrated to operators, which should alleviate their concern over acoustic shock, which further reduces the likelihood of an acoustic shock occurring.

Additional features of this embodiment include:

Identification of the high pitched narrow band signal by computation of the frequency spectrum of the incoming sounds, and comparison of the level at each frequency with the level at nearby frequencies.

Creation of band-reject filters having centre frequencies that approximately match the frequencies closest to the frequencies of the shrieks detected.

Rapid but progressive fading-in and fading out of the filters.

Use of a filter with frequency characteristics inverse to that of the receiving transducer used so that the maximum level at eardrum can be limited in a controlled manner as a function of frequency.

Implementation of the manual volume control such that some of the gain variation occurs prior to limiting and some occurs subsequent to liming.

Application of dual-speed compression limiting to the prevention of acoustic shock.

Variation of the operation of the automatic volume control depending on whether the operator is speaking or silent.

Presetting the gain of the automatic volume control at the start of each new call.

Decreasing the gain of the automatic volume control whenever the incoming call level drops below a predetermined value.

### BRIEF DESCRIPTION OF THE DRAWINGS

The drawings appended hereto and described below are illustrative of embodiments of the invention and should not be construed as limiting the invention to only those embodiments described.

FIG. 1 is a block diagram of a digital signal processing system of an embodiment of the invention;

FIG. 2 is a block diagram illustrating in more detail the digital signal processing system of an embodiment of the invention;

FIG. 3 is a block diagram of a shriek rejecter shown in FIG. 2;

FIG. 4 is a block diagram of a shriek detector shown in FIG. 3;

FIG. 5 is a block diagram of a shriek finder shown in FIG. 4;

FIG. 6 is a block diagram of a shriek rejection filter shown in FIG. 3;

FIG. 7 is a z-plane illustration of the shriek rejection filter of FIG. 6;

FIG. 8 is a block diagram of a filter depth controiller shown in FIG. 6;

FIG. 9 is a block diagram of a filter coefficient generator shown in FIG. 6;

FIG. 10 is a block diagram of a filter stage shown in FIG. 6;

FIG. 11 is a block diagram of a filter gain compensation module shown in FIG. 6;

FIG. 12 is a graph comparatively illustrating the effect of shriek rejection according to an embodiment of the invention;

FIG. 13 is a perspective view of an apparatus of an embodiment of the invention; and

FIG. 14 is a block diagram of internal components of the apparatus of an embodiment of the invention;

### DETAILED DESCRIPTION OF THE PREFERRED EMBODIMENTS

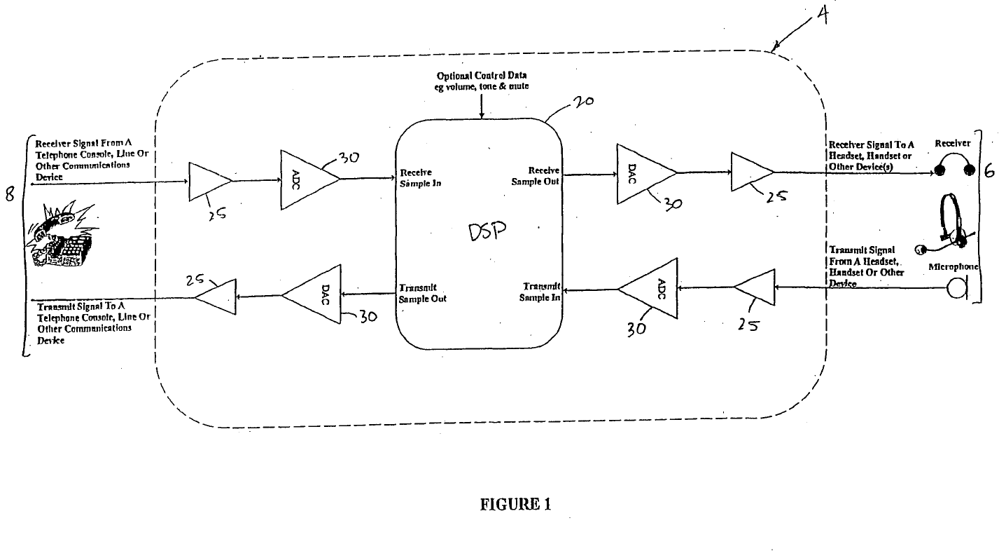

With reference to FIG. 1, preferred embodiments of the invention relate to an interface device 4 for communicating with a headset 6 and telephony device 8. The interface device 4 is powered by a power supply 10 (not shown), which is either separate or alternatively derived from telephony device 8.

The interface device 4 receives incoming telephony signals from the telephony device 8 in analogue form, digitally processes (in DSP 20, the operation of which is described below) these signals after D/A conversion 30 and forwards the signals on to the headset 6 (after reconversion to analogue form). The interface device 4 acts as a sound shield and screens out unwanted audio signals from interface device 8 in favour of normal voice signals. The interface device 4 also receives voice signals back from the headset 6 and passes these through to the telephony device 8 without processing by the digital signal processor (described (later). However, if a mute function of the interface device 4 is activated, voice signals received from headset 6 are blocked from transmission to the telephony device 8.

Digital-to-analogue and analogue-to-digital conversion functions 30 are performed by a CODEC coupled to the DSP 20. Additional processing 25 may be performed on the analogue signals.

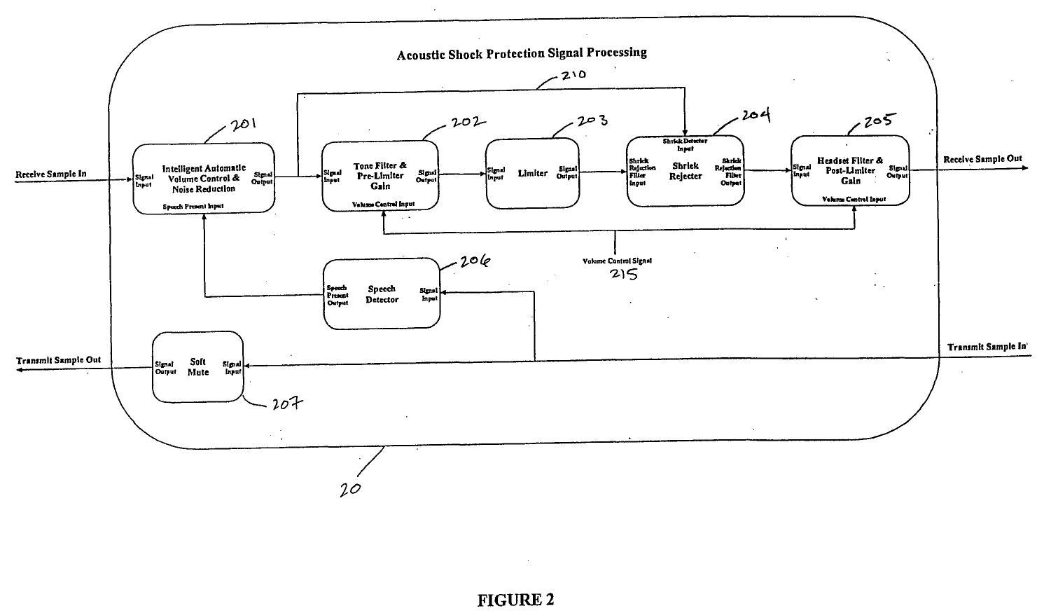

The signal processing modules of the interface device 4 are shown in FIG. 2. These modules are implemented as digital signal processing software loaded onto a digital signal processor integrated circuit.

An intelligent automatic volume control and noise reduction function operates as a slowly varying automatic volume control. It automatically alters the gain of the device to compensate for variations in level of the incoming calls. One feature of this device is that the gain is frozen at its previous value whenever the operator is talking. This prevents the problem of the gain slowly increasing when the caller is not talking because the caller is listening to the operator talk. A second feature is that the gain is rapidly set to a preset value at the start of a new call. The start of a new call is detected by monitoring for signalling tones that precede each call. A third feature is that the amount of gain is reduced once the level of the incoming call falls below some pre-determined amount. This is to prevent excessive amplification of line noise.

A tone and volume control function alters the gain as a function of frequency according to a preset frequency response curve. The manual volume control within this function enables the operator to vary the level of the sound emerging from the device by changing the gain of the device. Some of the gain variation caused by operation of the volume control is applied prior to the signal being limited, and some is applied after the signal is limited. Compared to altering the gain only subsequent to limiting, this combination reduces the small amount of distortion that would otherwise be caused by limiting the signal. Compared to altering the gain only prior to limiting, this combination minimizes the likelihood of unexpected strong input signals causing a high level at the output when the volume control has been adjusted to a lower setting.

A dual-speed limiter function limits the level of signal by rapid reduction of the gain. One signal detector causes a very rapid reduction of gain to a certain level. A second detector causes a less rapid reduction to a lower level.

A shriek detector function detects the presence of narrow-band, sustained sounds and measures their frequency or frequencies. Such sounds are not characteristic of speech, but are characteristic of sounds that lead to acoustic shock. Detection is achieved by calculating the frequency spectrum of the sound present during short, successive intervals of time. If the level at one frequency exceeds the level at nearby, but not immediately adjacent, frequencies by more than a predetermined amount, and if this condition is maintained for more than a predetermined amount of time, a shriek is determined to be present at that frequency.

A shriek rejection filter function rapidly applies a band-reject filter or filters to reduce the gain at the frequency or frequencies at which the shriek detector has determined a shriek to be present. A feature of this is that the degree of attenuation provided at the frequency of the shriek is progressively increased as the duration of the shriek increases. This feature prevents degradation of sound quality if the shriek detector incorrectly and momentarily indicates that a shriek is present.

A headset correction filter function imparts a gain-frequency response related to the inverse of the frequency response characteristic of the headset/headphones connected to the device. Different frequency response curves are downloaded to, and stored in, the device as part of or following manufacture, and will be applicable depending on the frequency characteristic of the individual headset/headphones connected to the device. The frequency characteristic of the correction filter is designed to compensate for deficiencies in the frequency characteristic of the headset/headphones.

An embodiment of the acoustic shock protection signal processing is shown in FIG. 2. The DSP 20 receives a digital encoded signal at the input labeled Receive Sample Input, processes this signal and transmits this processed signal from an output labeled Receive Sample Output. The DSP 20 receives an additional digitally encoded signal at the input labeled Transmit Sample Input, processes this signal and transmits this processed signal from an output labeled Transmit Sample Output.

Alternatively, the algorithm can be configured to operate without the Transmit Sample Output and without the processing block labeled Soft Mute 207. Alternatively, the DSP 20 can be configured to operate without the Transmit Sample Input and without the block labeled Speech Detector 206.

The digitally encoded signals are in pulse code modulated form. The DSP 20 receives the digitally encoded signals one sample at a time, processes these signals one sample at a time and transmits these processed signals one sample at a time. The DSP 20 receives a new sample at its input, processes the sample and transmits the processed samples every 125 microseconds. This sampling period of 125 microseconds corresponds to a sampling frequency of 8,000 Hz. Alternatively, the DSP 20 can be configured to operate at other sampling frequencies.

In the following descriptions, the sample passed from the Transmit Sample Input to the Transmit Sample Output via the intervening processing is referred to as the transmit sample and the path through the intervening processing is referred to as the transmit path. The transmit sample or sample sequence is also referred to as the transmit signal. Likewise, the sample passed from the Receive Sample Input to the Receive Sample Output via the intervening processing is referred to as the receive sample and the path through the intervening processing (through modules 201-205) is referred to as the receive path. The receive sample or sample sequence is also referred to as the receive signal.

The transmit sample is processed prior to the receive sample, including processing of the transmit sample by a Speech Detector 206, which uses known methods to detect the presence of speech signals within an input signal. The receive sample is sequentially processed by each block in the receive path, which consists of the Intelligent Automatic Volume Control & Noise Reduction 201, the Tone Filter & Pre-Limiter Gain 202, the Limiter 203, the Shriek Rejecter 204 and the Headset Filter and Post-Limiter Gain 205. A copy of the receive sample from the Signal Output of the block labeled Intelligent Automatic Gain Control & Noise Reduction 201 is kept for subsequent use by the block labeled Shriek Rejecter 204 via path 210.

Alternatively, the DSP 20 can be configured to only contain the receive path processing. Alternatively, a Speech Present signal from the Speech Detector 206 applied to the Speech Present Input of the Intelligent Automatic Volume Control & Noise Reduction 201 can be disabled, set to zero and only a change in functionality of this processing block related Speech Present signal being active will be affected. Alternatively, the DSP 20 may be configured to operate with one or more of the processing blocks within the receive path removed. For example, all the processing blocks may be removed with the exception of the Shriek Rejecter 204. In this case, the signals applied to the Shriek Rejecter's Shriek Detector Input and Shriek Rejection Filter Input come directly from the Receive Sample Input and the signal from the Shriek Rejection Filter Output is applied directly to Receive Sample Output. Alternatively, the signal applied to the Shriek Rejection Filter Input may be merely delayed relative to the signal applied to the Shriek Detection Input.

The Soft Mute block 207 sets its Signal Output to zero when instructed by an external control signal (not shown) to mute the trasmit signal. Otherwise the transmit sample is passed through the Soft Mute unaltered.

The Speech Detector 206 accepts the transmit signal from the Transmit Signal Input at its Signal Input and produces a binary signal called Speech Present at its Speech Present Output. This signal is a 1 if speech is present and 0 otherwise. Alternatively, the input to the Speech Detector may be from the Signal Output of the Soft Mute 207.

The Intelligent Automatic Volume Control & Noise Reduction block 201 accepts the receive signal at its Signal Input from the Receive Sample Input and produces a processed receive signal at its Signal Output. It accepts an additional binary signal at its Speech Present Input which represents the presence of speech in the transmit path.

The Signal Input is filtered in parallel by three IIR filters to produce three separate signals. The first filter attenuates frequencies in which standard telephone tones (i.e. dial tone, busy tone, ring tone) and telephone call presentation tones are present to form a tone rejected signal. The second filter attenuates all frequencies in which standard telephone tones are not present to form a standard tone signal. The third filter attenuates all frequencies in which telephone call presentation tones are not present to form a presentation tone signal. The short-term level of these signals is calculated. These short-term levels are called the short-term tone rejected level, the short-term standard tone level and the short-term presentation tone level.

The short-term level of each of the above signals is calculated using 1^{st} order envelope detectors. Each 1^{st} order envelope detector comprises of full-wave rectification, performed by taking the absolute value of the input sample to the envelope detector, the result of which is applied to a 1^{st} order “leaky integrator” with switchable coefficients.

The coefficients determine the time constants and are switched depending on whether the full-wave rectified input sample is greater than or equal to the previous envelope sample calculated. If the full-wave rectified input sample is greater than or equal to the previous calculated envelope sample then an attack coefficient and its corresponding input scaling factor are selected to be the A1 and B0 coefficients of the “leaky integrator” respectively. Otherwise a release coefficient and a zero input scaling factor are selected to be the A1 and B0 coefficients respectively. The envelope signal resulting from the “leaky integrator” increases exponentially at a rate determined by the attack coefficient when the full-wave rectified input sample is greater than or equal to the previous calculated envelope sample. Otherwise the envelope decreases exponentially to 0 at a rate determined by the release coefficient.

The tone rejected signal is also applied to an additional 1^{st} order envelope detector similar to that described above but using longer time constants to form a long-term level estimate called the long-term call level. This envelope detector also differs from the short-term envelope detectors in that it only operates under certain conditions. The long-term level estimate may be frozen or altered under certain conditions. These conditions depend on the level of the short-term level estimates and the presence of speech in the transmit path.

The long-term call level estimate will only track the tone rejected signal when:
1. there is no speech detected in the transmit path, Speech Present Input is 0 and
2. there are no standard tones present, this is deemed true if the ratio of the short-term standard tone level to the short-term tone rejected level is below a predetermined amount and
3. there are no presentation tones present, this is deemed true if the ratio short-term presentation tone level to the short-term tone rejected level is below a predetermined amount and
4. there is sufficient signal present to be tracked, ie the signal is not silence or merely low level noise, this is deemed true if the short-term tone rejected level is above a predetermined amount.

The long-term call level estimate is compared with a predetermined threshold. The gain of the Automatic Volume ControL AVC is a predetermined fixed gain if the long-term call level estimate is less than the predetermined threshold. Otherwise, the gain is equal to the predetermined gain multiplied by predetermined threshold and divided by the long-term call level estimate.

Whenever a new presentation tone is detected (not within a predetermined time from the last detection of a presentation tone) the current long-term call level estimate is sampled and is added to a history of recent long-term call level estimates to form a new historical average level of recent calls. Once a new presentation tone is detected the long-term call level estimate is gradually updated over a short predefined period so it is set to the average level of the recent calls in preparation for a new telephone connection with an unknown level. Once the presentation tone becomes absent a new telephone connection is deemed to have been made. The presentation tone is detected if the ratio short-term presentation tone level to the short-term tone rejected level exceeds a predetermined amount.

The level of standard telephone tones and presentation tones is suppressed if they are deemed excessive. Short-term suppression occurs if the ratio of the short-term standard telephone tone level to the short-term tone reject level exceeds a predetermined threshold or the ratio of the short-term presentation tone level to the short-term tone reject level exceeds a pre-determined threshold by a predetermined amount. The degree of suppression, or attenuation is determined by the amount that these ratios exceed their respective thresholds.

The detection of the standard telephone tones and call presentation tones may be achieved by other means applied to the Intelligent Automatic Volume Control & Noise Reduction's Input Signal such as peak frequency identification in the frequency domain obtained using Fast Fourier Transform analysis or other means, waveform zero-crossing rate detection analysis, analysis of the auto-correlation function, analysis of cross-correlation with known signal templates.

The Tone Filter & Pre-Limiter Gain 202 accepts the receive signal at its Signal Input from the Intelligent Automatic Volume Control & Noise Reduction block 201 Signal Output and produces a processed receive signal at its Signal Output. It accepts a Volume Control Signal 215 at its Volume Control Input which is used to calculate the pre-limiter gain. It also accepts an additional control signal (not shown) to select one of several different tone filters.

The input signal from the Signal Input is applied to the input of the tone filter 202. The signal from the output of the tone filter 202 is scaled by the pre-limiter gain and delivered to the Signal Output. The tone filter 202 is a 32-tap finite impulse response, FIR filter. Alternatively other lengths of FIR filters or other forms of tone filtering may be employed such as infinite impulse response, IIR filters. The main feature of this tone filter 202 is that determines the frequency response of the receive sound at the eardrum for signals below the level at which limiting occurs. To achieve this the FIR coefficients are calculated taking into consideration the effects of the headset frequency response and the headset filtering frequency response.

The pre-limiter gains have a non-linear relationship with the Volume Control Signal 215. The pre-limiter gains are obtained using the discrete Volume Control Signal 215 as an index to a lookup table which stores a discrete set of pre-limiter gain values. The non-linear relationship is such that there is no change in the pre-limiter gains for values of the Volume Control Signal 215 up to a predetermined value above which the pre-limiter gain values have a logarithmic relationship with the Volume Control Signal 215. The purpose of this is to provide no change in the amplification of the signal prior to the Lirniter up to a pre-defined volume control setting after which the signal passed to the following block labeled Limiter 203 is increased in level. This increase in level creates more limiting within the Limiter 203 which produces a perception of increased loudness but with little increase in maximum level produced at the eardrum. This increased level also increases the distortion produced by the limiter. This arrangement effectively mimics the distortion produced by an analogue amplifier that produces more distortion at high levels, when the volume is “turned up” but gives a “clean” signal at lower settings of the volume control.

The Limiter 203 accepts the receive signal at its Signal Input from the Tone Filter & Pre-Limiter Gain 202 Signal Output and produces a processed receive signal at its Signal. Output. The input signal from the Signal Input is split into three parallel paths and applied to the following three processes:
1. a fast speed envelope detector,
2. a very fast speed envelope detector,
3. a delay.

The fast speed and very fast speed envelope detectors are the same as the 1^{st} order envelope detectors described in the section on Intelligent Automatic Volume Control & Noise Reduction 201. The attack and release time constants for the very fast speed envelope detector are shorter than the fast speed envelope detector. Each envelope detector produces a short-term term level estimate of the signal but with different characteristics due to the different time constants employed. The short-term term level estimate from the fast speed envelope detector is called the fast envelope and the short-term level estimate from the very fast speed envelope detector is called the very fast envelope. Each envelope signal from each envelope detector is compared with its respective threshold. The threshold for the very fast envelope signal is higher than the threshold for the fast envelope signal. The limiting gain produced by each envelope signal is unity if the envelope signal is less than its respective threshold. If an envelope signal exceeds its respective threshold then the corresponding limiting gain is equal to the corresponding threshold divided by the envelope signal. In this manner two limiting gains are produced, the fast speed limiting gain and the very fast speed limiting gain. Due to the higher threshold associated with the very fast envelope signal the associated limiting gain it is less often below unity compared to the fast speed limiter gain. The time constants of the fast speed envelope detector are selected to mimic the loudness integration time constants of the human auditory system and thus the resulting gain reduces the likelihood of excessive loudness being experienced by the listener. The time constants of the very fast speed envelope detector are selected to minimise the effect of very fast rising high level changes in the signal which are potentially damaging to the auditory system of the listener. The final limiting gain is the minimum of the fast speed limiting gain and the very fast speed limiting gain.

The input signal from the Signal Input is also passed to a delay of predetermined length. The output from this delay is multiplied by the final limiting gain to produce the limited signal which is passed to the Signal Output. The advantage of this scheme is that delay compensates for the time taken for the envelope signals to rise in order for a reduction in the limiting gain to occur when a fast rising change in the signal level occurs. Therefore the effect known as “overshoot” is reduced.

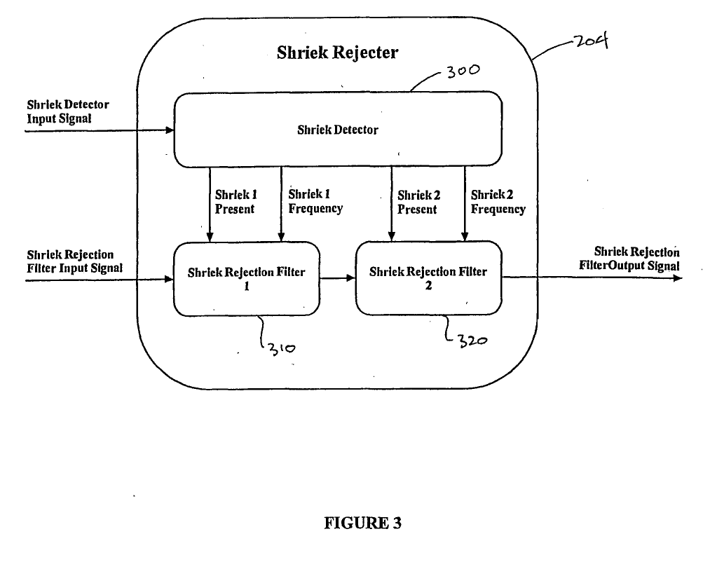

Referring to FIGS. 2 and 3, a Shriek Rejecter 204 accepts two signals, the Shriek Detector Input Signal and the Shriek Rejection Filter Input Signal. It produces one output signal, the Shriek Rejection Filter Output Signal. Both input signals originate from the same source however the input to a Shriek Detector 300 is taken prior to the input to Shriek Rejection Filter. This arrangement enables the signal applied to a Shriek Rejection Filter 310, 320 to be delayed with respect to the input to the Shriek Detector 204 and therefore the time taken to detect and reject shriek(s) can be compensated for by the delay introduced by the intervening processing. In addition, this arrangement provides a less processed signal to Shriek Detector 204 so that the detection of the shriek(s) is unaffected by tone or volume setting or limiting. It also enables the shriek(s) to receive the full effect of a Limiter 203 in addition to the full effect of the Shriek Rejection Filter.

Alternatively, the input to the Shriek Detector 300 and the input to the Shriek Rejection Filter 310 may both be fed the same signal, which may be either the Receive Sample In, the output of the Tone Filter & Pre-Limiter Gain 202, or the Output of the Limiter 203. Alternatively, the input to the Shriek Detector and the Shriek Rejection Filter may be fed from the same source but via different processing paths. An example of this is to provide a signal delay to the signal passed to the Rejection Filter.

As shown in FIG. 3, the Shriek Rejecter 204 includes a shriek detector (labeled Shriek Detector) and two adaptive filters, Shriek Rejection Filter 1 and Shriek Rejection Filter 2; The Shriek Detector identifies the presence and the frequency regions of up to two shrieks simultaneously. The Shriek Detector provides two signals to each Shriek Rejection Filter, a binary signal indicating the presence or absence of a shriek, Shriek Present and a number representing the frequency region in which the shriek is present, Shriek Frequency. The Shriek Detector may be configured to identify the presence and frequency region of additional shrieks and for this purpose, the Shriek Rejecter may contain additional Shriek Rejection Filters and the Shriek Detector may provide additional signals to indicate presence and frequency region of additional shrieks to the additional Shriek Rejection Filters.

Each Shriek Rejection Filter provides narrow-band attenuation of the signal passing through it when its Shriek Present input is active by adaptively defining a notch filter. The centre frequency of its narrow-band attenuation is determined by the number provided to its Shriek Frequency input.

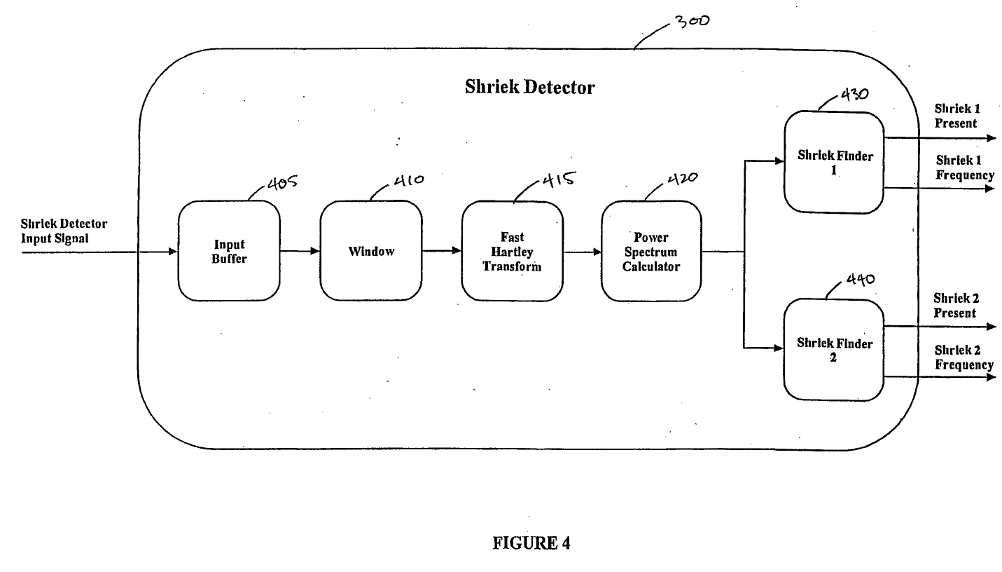

The Shriek Detector 300 shown in FIG. 4 provides identification of the presence and frequency region of up to two shrieks simultaneously. The Shriek Detector 300 accepts samples at its Shriek Detector Input which it places in an Input Buffer 405. When the input Buffer 405 is full with a block of K samples (K=64) a block of data is deemed to have been collected, this is called an analysis block. A Window function 410 (Hanning) of K data points is applied to this block of samples. The windowing function 410 is applied to reduce spectral leakage in the following frequency analysis. The windowed data is then applied to a K point Fast Hartley Transform 415 to form K complex frequency samples. The data from the Fast Hartley Transform 415 is applied to a Power Spectrum Calculator 420 which forms an estimate of the power spectrum of the block of data. The estimate of the power spectrum comprises an array of spectral frequency bands or bins up to and including Fs/2, spaced at Fs/K Hertz apart, where Fs is the sampling frequency (preferably, Fs=8 kHz). Each of the shriek finders, Shriek Finder 1 (430) and Shriek Finder 2 (440) analyse the power spectrum to determine if a shriek(s) is present and the frequency region in which the shriek(s) is located. Each Shriek Finder 430, 440 produces a binary signal, Shriek Present indicating the presence (logic 1) or absence (logic 0) of a shriek and a number representing the frequency band or ‘bin’ in which the shriek is present, the Shriek Frequency. Each Shriek Finder operates on a separate spectral region, the first operates on the region from below 2,437.5 Hz and second above 2,437.5 Hz. Alternatively, both Shriek Finders may operate over the same spectral range with a condition that the second Shriek Finder is precluded from identifying a shriek in a frequency region in which the first Shriek Finder has found a shriek. Alternatively, additional Shriek Finders may be incorporated to identify the presence and frequency region of additional shrieks.

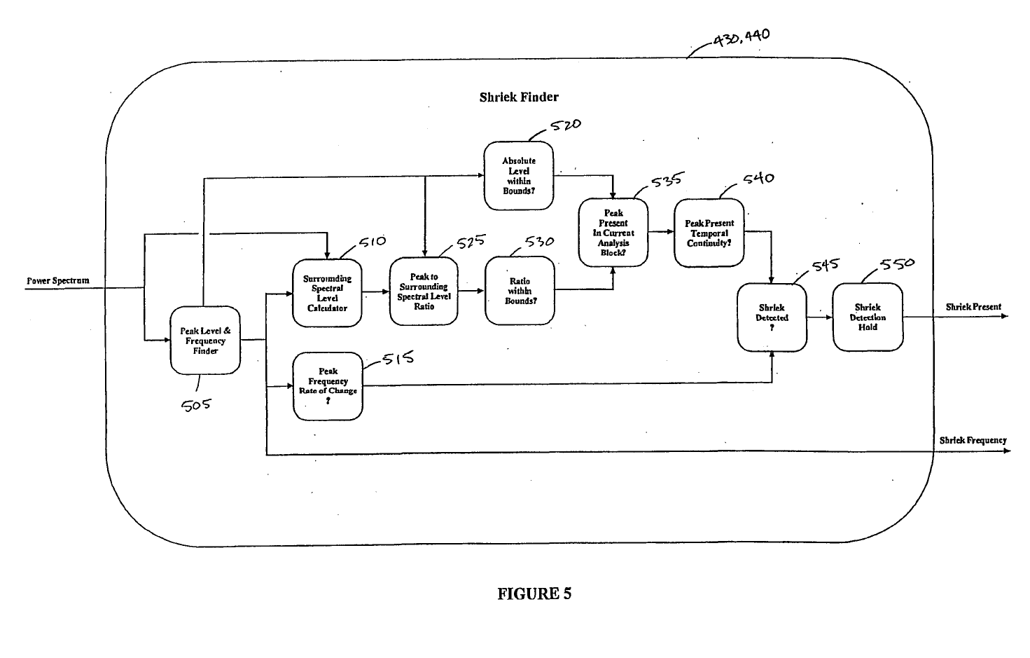

Referring now to FIG. 5, both Shriek Finders 430, 440 are identical with the exception of their defined frequency range and therefore only one is described. A Peak Level & Frequency Finder 505 scans the power spectrum array within a defined range for the maximum value. The defined range for Shriek Finder 1 is the power spectrum bins from 8 to 19 (1,000 Hz to 2,375 Hz). The defined range for Shriek Finder 2 is the power spectrum bins from 20 to 32 (2,500 Hz to 4,000 Hz). The maximum value found is recorded as the peak level and the power spectral bin number is recorded as the Shriek Frequency.

A Surrounding Spectral Level Calculator 510 uses the Shriek Frequency number to calculate the average spectral power in the surrounding power spectrum bins excluding the bin immediately above and the bin immediately below the bin containing the peak level. The average is derived from four bins comprising the two bins offset by two and three above the bin containing the peak level, and the two bins offset by two and three bins below the bin containing the peak level, except in the following two cases. Case 1: when the frequency bin containing the peak level is above bin 28 (3,500 Hz) but below bin 31 (3,875 Hz) the average is derived from the two bins offset by two and three below the bin containing the peak level. Case 2: when the frequency bin containing the peak level is above bin 30 (3,750 Hz) the average is derived from the two bins offset by three and four below the bin containing the peak level.

A Peak to Surrounding Spectral Level Ratio block 525 calculates the ratio of the peak power level to the average surrounding power spectral level. This ratio is compared to a predetermined threshold by the Ratio Within Bounds operation 530. The peak power level is compared to a pre-determined threshold by the Absolute Level Within Bounds operation 520. If the ratio of the peak power to the average surrounding power spectral level exceeds a predetermined threshold and the absolute peak power level also exceeds a predetermined threshold then a peak is deemed to be present in the current analysis block by the Peak Present In Current Analysis Block 535.

A history of the peaks present in previous analysis blocks is stored by the Peak Present Temporal Continuity operation 540. If a peak was present in the previous analysis block and is also present in the current analysis block then temporal continuity of the peak is deemed to exist.

A history of the Shriek Frequencies in previous analysis blocks is stored by the Peak Frequency Rate Of Change block 515. If the Shriek Frequency found in the current analysis block does not differ by more than a predetermined amount, one bin (+/−125 Hz) compared to the Shriek Frequency found in the previous analysis block then the Peak Frequency Rate Of Change is deemed to be within the bounds.

If there is both temporal continuity in the presence of a peak and the peak frequency rate of change is within bounds then a shriek is deemed to be detected by the Shriek Detected operation 545. If a shriek is detected then the Shriek Present flag is set to logic 1. The Shriek Detection Hold operation 550 will maintain the Shriek Present set state for pre-determined number of analysis block periods (for example, 12) following each time a shriek is detected, after which it will set the Shriek Present flag to logic 0.

Alternative methods for detecting the presence of a shriek and for finding the frequency of the shriek, such as those based on analysis of the autocorrelation function, or those based on the zero-crossing rate of the signal, could be used instead of the methods described above.

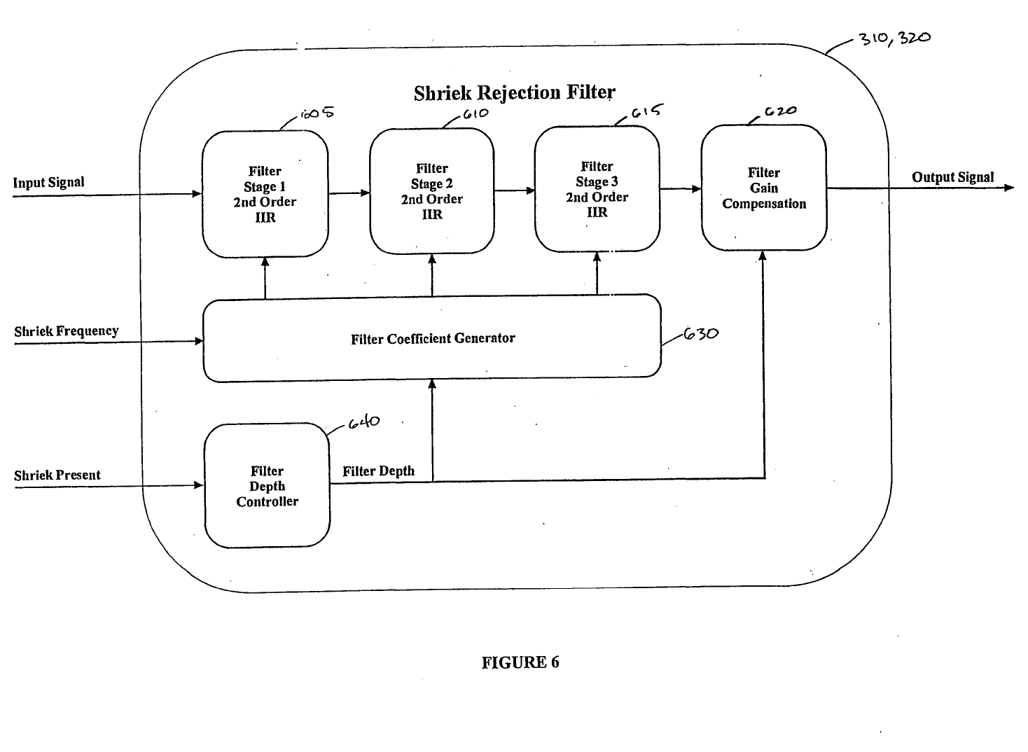

Both Shriek Rejection Filters 310, 320 are identical in design and therefore only one is described referring to FIG. 6, the Shriek Rejection Filter 310, 320 is a variable-depth, frequency-agile, sixth-order infinite impulse response (IIR) filter designed to provide narrow-band attenuation (notch filtering). The signal to be filtered is passed through a cascade of three 2^{nd} order IIR filters, Filter Stage 1 (605), Filter Stage 2 (610) and Filter Stage 3 (615) and the Filter Gain Compensation operation 620 before being passed to the output. The narrow-band attenuation of the signal occurs when its Shriek Present input is active. The centre frequency of the narrow-band attenuation is determined by the number provided to its Shriek Frequency input.

A Filter Depth controller 640 provides rapid but smooth fading in of the filters when the Shriek Present signal becomes active (shriek present) and slower fading out of the filters when the Shriek Present signal becomes inactive (shriek absent). The smoothing gives a smoother sound quality and prevents audible clicking when the filters are activated- and deactivated. It also reduces the disturbance to the sound should the Shriek Rejection be briefly activated by speech. A Filter Coefficient Generator 630 generates coefficients for the three 2^{nd} order IIR filters 605, 610, 615 according to the Shriek Frequency and Filter Depth it receives. The coefficients immediately change with a change in the Shriek Frequency, which may change after every analysis block is complete. Alternatively, the interpolation may be employed during the coefficient generation process so that the coefficients smoothly change between one set of values to another. The Filter Gain Compensation 620 compensates for the effect the filtering has on the gain at frequencies other than within the narrow-band attenuation region.

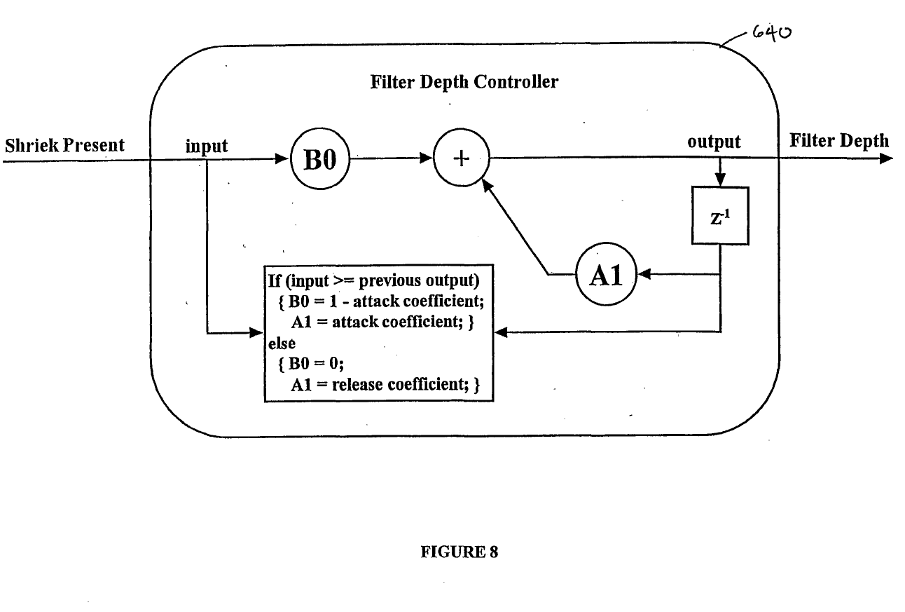

Referring now to FIG. 8, the Filter Depth Controller 640 is a 1^{st} order “leaky integrator” with switchable coefficients. The coefficients determine the time constants and are switched depending on whether the input sample is greater than or equal to the previous output sample. If the input sample is greater than or equal to the previous output sample then the attack coefficient and its corresponding input scaling factor are selected; otherwise the release coefficient and a zero input scaling factor are selected. The Filter Depth increases exponentially to 1 at a rate determined by the attack coefficient (0.9384) when the Shriek Present signal becomes active (1). The Filter Depth decreases exponentially to 0 at a rate determined by the release coefficient (0.9835) when the Shriek Present signal becomes inactive (0).

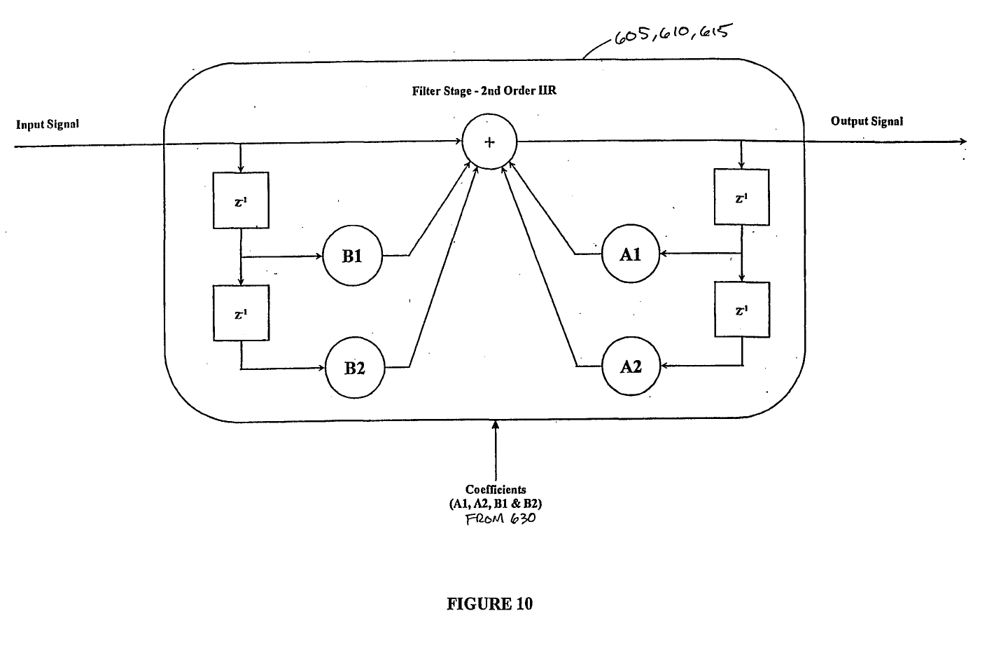

As shown in FIG. 10, each filter stage 605, 610, 615 comprises a direct form implementation of a 2^{nd} Order IIR. All four coefficients shown may be varied.

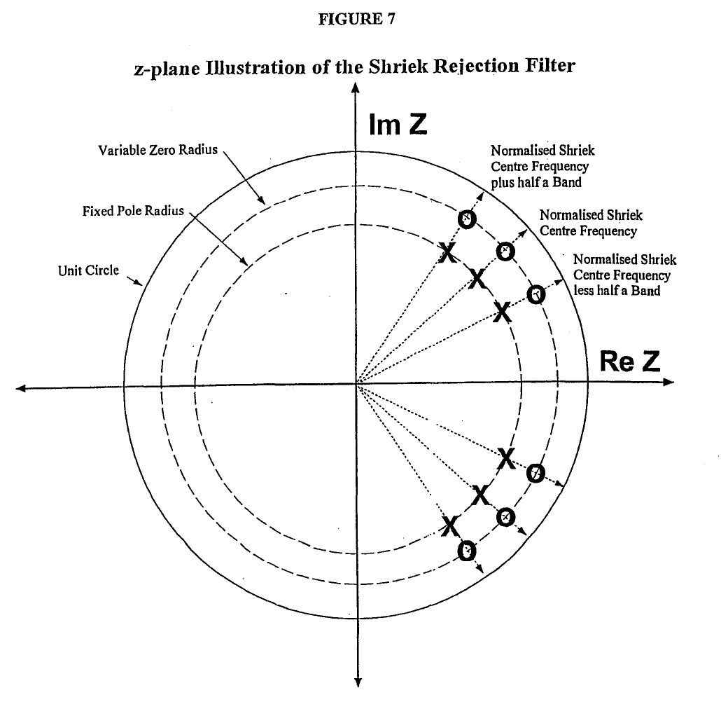

With reference to FIG. 7, each 2^{nd} order filter stage comprises of a pair of poles and a pair of zeros on the z-plane. The zeros from each 2^{nd} order filter stage lie on the same angle around the z-plane as the poles from the same filter stage. The angular position of the pairs of poles and zeros is determined by the Shriek Frequency. The angular position of the middle pair of poles and zeros corresponds to the centre of the frequency region defined by the Shriek Frequency. The angular position of the high frequency pair of poles and zeros corresponds to the Shriek Frequency plus half the bandwidth of the Shriek Detector's frequency analysis band (62.5 Hz). Likewise, the angular position of the low frequency pair of poles and zeros corresponds to the Shriek Frequency less half the bandwidth of the Shriek Detector's frequency analysis band (62.5 Hz).

The Poles all lie on a fixed radius of 0.8 from the centre of the z-plane. The zeros vary together in their distance from the centre of the z-plane from a radius of 0.8 to a radius of 1.0. Their position is determined by the Filter Depth. When the Filter Depth is 0 the zeros lie at a radius of 0.8 and therefore cancel the effect of the poles. This results in no filtering of the input signal. As the Filter Depth increases from 0 to 1 the zeros move from their position at a radius of 0.8 to a position on the unit circle (a radius of 1.0) where together they provide their greatest narrow-band attenuation of the input signal.

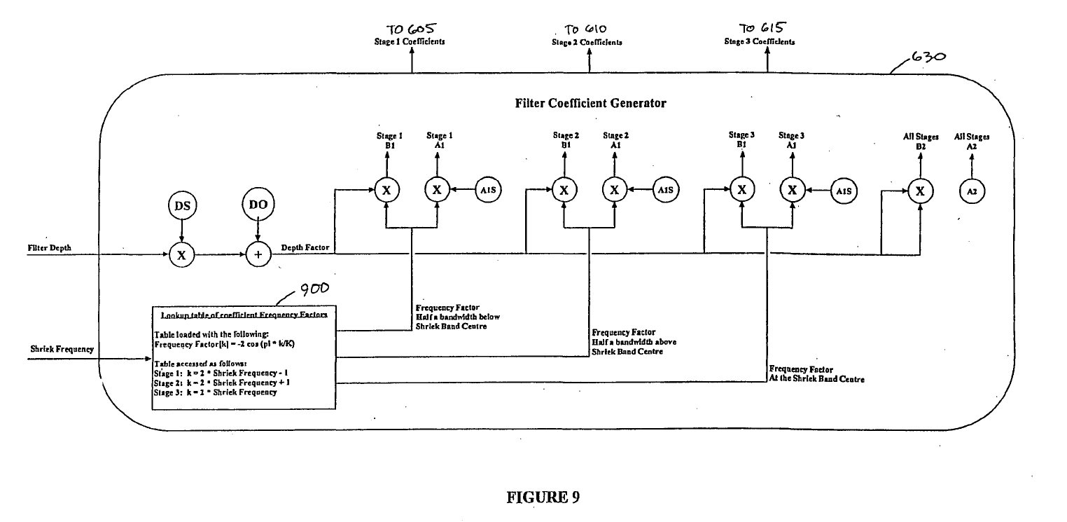

With reference to FIG. 9, the Filter Coefficient Generator 630 generates the coefficients for the three 2^{nd} order IIR filters in response to the Shriek Frequency and Filter Depth signals. The frequency or angle on the z-plane of the poles and zeros is determined by the Shriek Frequency signal. The centre frequencies of each of the 2^{nd} Order ILK Filter Stages are:
Filter Stage 1: Shriek Frequency−½ the bandwidth of a Shriek Detectors analysis band
Filter Stage 2: Shriek Frequency+½ the bandwidth of a Shriek Detectors analysis band
Filter Stage 3: Shriek Frequency

The frequency dependent parts of the coefficients, Frequency Factors for all three. Filter Stages are obtained from a lookup table that contains 65 values corresponding to frequencies from 0 Hz up to 4 kHz in 62.5 Hz steps. The table is generated using the following relationship:

$$Frequency Factor [ k ] = - 2 \cdot cos ( π \cdot \frac{k}{K} )$$

where: k is the frequency index which ranges from 0 to 64,
K is the number of frequency divisions from 0 Hz to half the sampling frequency, 64.

The Frequency Factors for each of the filter stages is obtained from a Frequency Factor lookup table 900 using the following relationships between the lookup table frequency indexes and the Shriek Frequency number:
Stage 1: k=2*Shriek Frequency−1
Stage 2: k=2*Shriek Frequency+1
Stage 3: k=2*Shriek Frequency
   The variable Depth Factors for each of the filter stages is obtained from the Filter Depth using the relationship:
   Depth Factor=Filter Depth·DS+DO
   where: DS is the Depth Scale (0.2)
   DO is the Depth Offset (0.8)

This results in the Filter Depth with a range from 0 to 1 being mapped to a Depth Factor with a range from 0.8 to 1.0.

The final coefficients are formed using the following relationships:

Filter Stage 1:

B1=Frequency Factor[2*Shriek Frequency−1]*Depth Factor
A1=Frequency Factor[2*Shriek Frequency−1]*A1S where A1S is −0.8
   Filter Stage 2:
B1=Frequency Factor[2*Shriek Frequency+1]*Depth Factor
A1=Frequency Factor[2*Shriek Frequency+1]*A1S where A1S is −0.8
   Filter Stage 3:
B1=Frequency Factor[2*Shriek Frequency]*Depth Factor
A1=Frequency Factor[2*Shriek Frequency]*A1S where A1S is −0.8
   For all three stages
B2=Depth Factor*Depth Factor
A2=−0.64

The B1 and A1 coefficients immediately change in response to step changes in the Shriek Frequency that may occur at the end of every analysis block. Alternatively, interpolation may be applied to the Frequency Factors specific to each filter stage to provide a smooth transition of coefficients between analysis blocks.

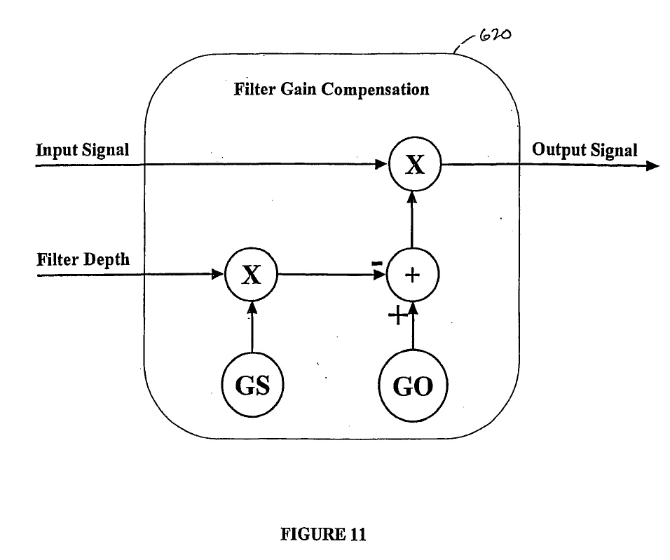

Referring to FIG. 11, the Filter Gain Compensation block 620 receives an input signal from Filter Stage 3 which it scales and passes to its output. The Gain Compensation is dependent on the Filter Depth it receives from the Filter Depth Controller 640. The Gain Compensation is obtained from the Filter Depth using the relationship:
Gain Compensation=GO−Filter Depth·GS
where: GO is the Gain Offset (1.0)
GS is the Gain Scale (0.45)

This results in the Filter Depth with a range from 0 to 1 being mapped to a Gain Compensation with a range from 1.0 to 0.55.

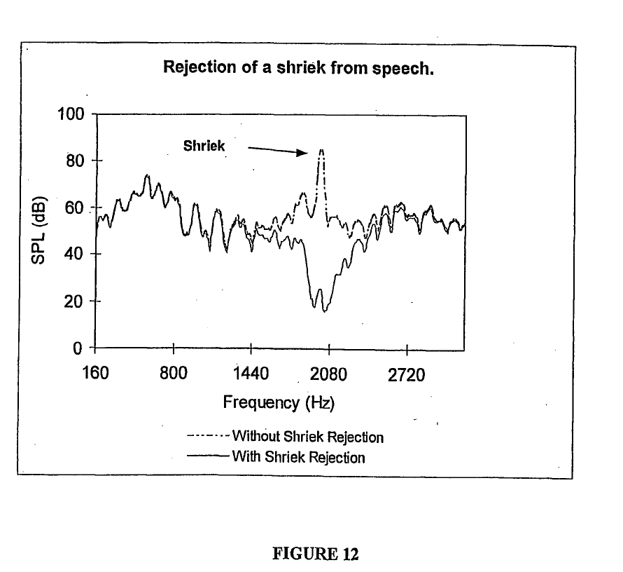

FIG. 12 is a graph of a spectral analysis of the output of the device with and without Shriek Rejection according to the presently described method. The input signal is speech combined with a high-level, high-pitch tone or shriek at 2 kHz. The Shriek Rejecter has suppressed the 2 kHz tone by about 60 dB while leaving most of the speech frequencies unaffected. This required the activation of only one of the two Shriek Rejection Filters 310, 320. The general attenuation within the desired rejection bandwidth (125 Hz) of each Shriek Rejecter is at least 40 dB.

Referring again to FIG. 2, the block labeled Headset Filter & Post-Limiter Gain 205 accepts the receive signal at its Signal Input from the Shriek Rejecter's Shriek Rejection Filter's Output and produces a processed receive signal at its Signal Output. It accepts a Volume Control Signal 215 at its Volume Control Input which is used to calculate the post-limiter gain. It also accepts an additional control signal (not shown) to select one of many different headset filters.

The input signal from the Signal Input is applied to the input of the headset filter. The signal from the output of the headset filter is scaled by the post-limiter gain and delivered to the Signal Output. The headset filter is a 64-tap finite impulse response, FIR filter. Alternatively other lengths of FIR filters or other forms of filtering may be employed such as infinite impulse response, IIR filters. The main feature of this headset filter is that it determines the maximum sound level as a function of frequency at the eardrum for signals above the level at which limiting occurs. To achieve this the FIR coefficients are calculated taking into consideration the effects of the headset frequency response measured at the eardrum. This enabled the maximum sound pressure level at the eardrum to be prescribed at each frequency. Filter coefficients for a variety of headsets or headset types are stored. A given set of these stored coefficient is be selected according to the headset in use by an additional control signal (riot shown). This enabled the algorithm to control the maximum sound pressure level at the eardrum in a prescribed manner for any headset, handset or other receiving transducer.

The post-limiter gains have a non-linear relationship with the Volume Control Signal. The post-lirniter gains are obtained using the discrete Volume Control Signal as an index to a lookup table which stores a discrete set of post-limiter gain values. The non-linear relationship is such that the post-limiter gain values have a logarithmic relationship with the Volume Control Signal up to a predetermined value above which the post-limiter gain values remain constant with higher values of the Volume Control Signal. The purpose of this is to provide a proportional change in the sound level experienced by the user with changes in the volume control settings up to a predefined volume control setting. In excess of this pre-defined level there is no change in the amplification of the signal post the Limiter. The pre-limiter gain increases above this volume control setting and thus a perception of increased loudness is experienced by the listener but with little increase in maximum level produced at the eardirum.

Alternative methods of attenuation of the narrow-band signals (shrieks), such as those based on adaptive FIR filtering or short-term spectral analysis, synthesis and modification by discrete Fourier Transforms may be used in addition to or in substitution of the notch filtering described above.

The methods and techniques described herein may be employed by devices other than a telephony interface device, although for the purposes of illustration, this description relates primarily to the application of the invention to telephony interface devices.

User Interface Functions

The interface device 4 user interface serves two main purposes. Firstly it allows a user to adjust and display such device variables as Volume and Tone (plus other variables). This is referred to as the User Role (UR). Secondly, it allows the manufacturer to configure the device for working with various models of headset and types of host/console (ie the telephony device to which the interface device is connected). This is referred to as the Maintenance Role (MR).

A variable is any operational parameter that can be adjusted using one or a combination of controls. Variable values are displayed using LED indicators.

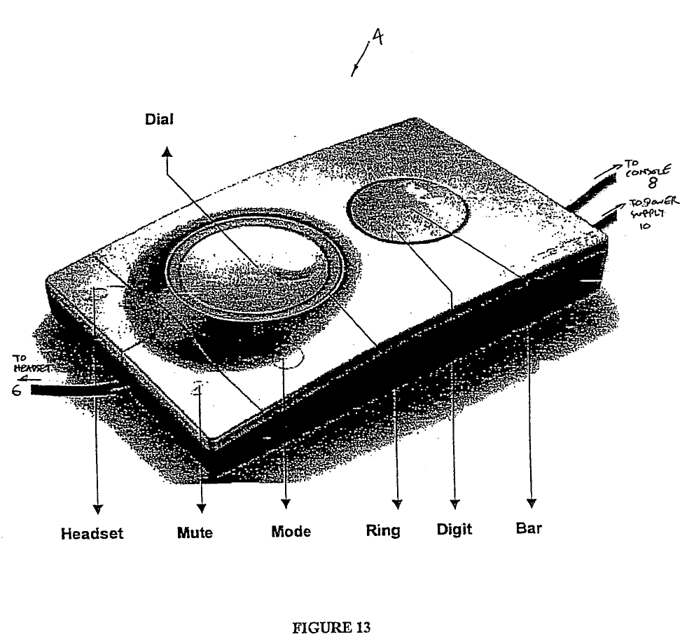

Interface Object Definition (Refer to FIG. 13)

Dial—This is a rotary controller for adjustment of variable values. Clockwise movement increases the value. Anti-clockwise movement decreases the value.
Headset button—This is a control for switching the audio path between headset and handpiece ports.
Mute button—This is a control for muting and un-muting the headset microphone. When pressed in combination with Mode, the Mute button changes operation to MR
Mode button—This is a control for selecting the variable to be adjusted by the Dial. When pressed in combination with Mute, the Mode button changes operation to MR.
Ring LED—This is a tri-colour indicator for indication of the Interface device 4 operational status (e.g. Muted or otherwise).
Digit LED—This is a single digit, 7 segment indicator for displaying integer variables and dial mode.
Bar LED—This is a ten segment, horizontally aligned indicator for displaying level variables.

Variables are only valid or in use when the headset is selected. When the handpiece is selected, the interface device 4 functionality is bypassed as the handpiece is connected directly to the host/console.

The volume control is used by the interface device 4 to control signal level presented to the headset earpiece. Volume assumes values between 1 and 20, 1 being minimum and 20 being maximum. At power on, Volume is restored to the value it held prior to power being removed.

The tone control (Tone) is used by the interface device 4 to control the timbre of the signal presented to the headset earpiece. Tone assumes values of LOW, MID and HIGH. LOW enhances lower frequencies with respect to MID. MID is the reference response. HIGH enhances higher frequencies with respect to MD. At power on, Tone is restored to the value it held prior to power being removed.

A headset type selection function is used by the interface device 4 to select headset frequency response modification filters and level normalisation for each of the supported headset types. HeadsetType assumes values 0 to 19, allowing up to 20 Headset profiles (HeadsetType 0 selects the test headset that causes the signal processing module to pass through all signals without frequency correction or level normalisation. It is used for maintenance and test purposes).

The User Interface control software does not allow selection of a HeadsetType for which no profile data is available. Ie. If the interface device 4 contains data for 5 headset profiles, selection of an HeadsetType higher than 5 will not be permitted. At power on, HeadsetType is restored to the value it held prior to power being removed.

Hardware

The core of the hardware is a 32 bit floating point Digital Signal Processor (such as Texas Instruments TMS320VC33PMC60). A support micro-controller (such as Atmel AT90LS8535) is incorporated to provide control and communication interfaces for the device.

Analogue signals are converted to digital form and digital to analogue by a 16 bit, 2 channel CODEC (such as AKM AK4532 (COder DECoder)). Audio signals are converted using a sampling frequency of 8 kHz providing 4 kHz audio bandwidth suitable for telephony communications. The CODEC performs anti-alias filtering.

Interface device 4 is powered using an external DC supply. Required system voltages are derived (refer to FIG. 13 Schematic sheet 6) from the external DC using linear regulators (National Semiconductor LM1117).

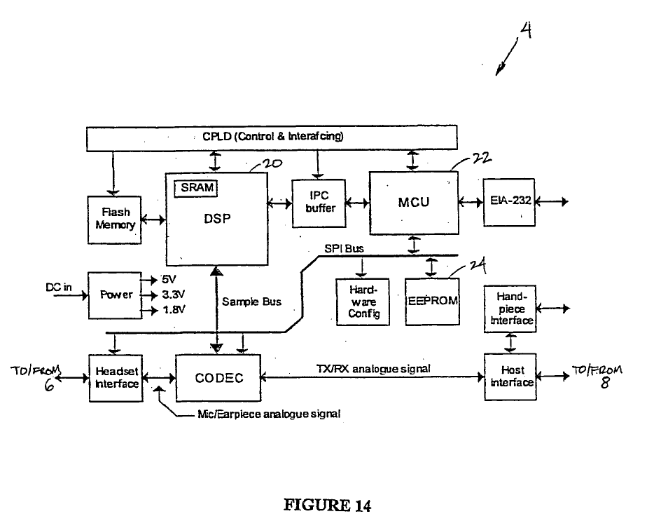

FIG. 14 illustrates the interconnection of the system in block diagram form.

To maintain compatibility with the majority of telephony devices, modular connectors (Four position; four contact (RJ11 type)) based on FCC-68 specifications are used for host and handpiece interfaces.

The existing handpiece from the host can be connected to Interface device 4 and selected for use by a push button control.

During power failure, connection is maintained between the host and its hand-piece to allow continued operation of the telephone system. When power is available and the handpiece is not selected, the headset will be connected, via Interface device 4 to the host.

The four wire host interface is transformer isolated from Interface device 4 allowing compliance with Australian and International safety requirements.

The two conductors that connect the handpiece receiver to the host will be called the receive pair. The two conductors that connect the handpiece microphone to the host will be called the transmit pair.

A DC shunt is connected across the receive pair to present a load similar to a handpiece to the host. The interface device 4 receive input is AC coupled and incorporates some filtering and protection components (clamping for large signal inputs and filters for high frequency attenuation). Signal level presented to the analogue to digital converter (ADC) input is adjusted within the CODEC analogue front end (The CODEC is configured by the MCU which stores configuration information in internal EEPROM.).

A DC shunt is provided across the transmit pair to simulate the presence of an electret microphone (some hosts sense the presence of a headset by the microphone supply current). The interface device 4 transmit output is also AC coupled and incorporates 30 protection and filtering components. The CODEC output is buffered using an op-amp that drives the isolation transformer, providing signal for the host input.

Transmitted level is controlled using an attenuator in the CODEC analogue front end.

Core Digital Section

Digital Signal Processor

Interface device 4 is designed around a high performance floating point Digital Signal Processor (DSP) chip. The selected DSP is normally clocked at 60 MHz and executes up to 60 million instructions or 120 million floating point operations each second which allows up to 7500 instructions or 15000 floating point operations each 125 us sample period. The DSP software uses part of this processing resource. Part is used by management and configuration utilities. A fair proportion remains available to implement functional enhancements or processing improvements.

The DSP is normally configured to operate in microcontroller mode which means it uses an internal boot-loader to load an application from external memory after it has been reset (see Microcontroller (MCU) discussion below). The boot process is described in the DSP user documentation provided by the manufacturer.

After boot and configuration, the DSPs primary function is to receive audio samples from the CODEC via an high speed serial data interface (I²S interface), manipulate each sample and re-transmit it some time later (the signal treatment code introduces a delay between input and output of a sample) via the same serial interface.

Sample Data Transfer

Data is transferred between the DSP and CODEC using a high speed synchronous serial interface that partly conforms to the I²S (Inter-IC Sound) defacto standard. Samples are transferred in 32 bit frames consisting of 2, 16 bit samples. The interface is bidirectional so each 125 us period, 32 bits are transferred from the DSP to the CODEC and 32 bits from the CODEC to the DSP. The bit clock is set to 256 kHz.

The samples coming from the CODEC for processing are of the headset microphone and host receive signals. The samples sent to the CODEC for output are the processed sample destined for the headset earpiece and a dummy sample (The microphone signal is routed through the CODEC analogue front end to the host transmit connection to avoid conversion delays. The microphone signal is sampled for the speech and background noise detection functions of the signal processing software).

The DSP requires two supply voltages; 3.3V for inputloutput and 1.8V for the processing core.

Micro-Controller

The Micro-Controller Unit (MCU) is responsible for system management and control. Specifically it performs the following:
Controls system start-up.
Manipulates Interface device 4 hardware configuration registers.
Manipulates CODEC control registers.
Initialises a communications channel between itself and the DSP.
Provides an asynchronous serial interface to Interface device 4 for maintenance activities.

Manages user and configuration settings.
Monitors and responds to user controls.
Maintains the user display.
Power management of the system.

The MCU contains non-volatile memory for storage of it's application and SRAM for temporary data. The application executes directly from the non-volatile memory. EEPROM is provided for storage of data that can be altered during Interface device 4 operation but must be retained when power is not available. EEPROM is used by the interface device 4 for storage of user settings (volume and tone) and configuration settings (transmit gain, receive gain, headset profile number and acoustic limiter number). It is also used to store initialisation values for the system hardware and passwords for access to maintenance functions.

The MCU contains an internal watchdog timer that is used to ensure correct program execution.

The MCU can be programmed in-system allowing modification of it's functionality without replacement of the device.

The MCU utilises a variety of standard and custom communications protocols to configure hardware registers, read push button states, analyse control dial movements, communicate with a maintenance system and exchange data with the DSP.

Inter Processor Communication

An 8 bit parallel interface is used to exchange data between the DSP and MCU. This interface allows high speed transfer of information between the devices which is required to allow maximum DSP time for signal processing tasks. Each device controls a request signal to alert the other of pending exchanges. A common ˜BUSY signal is used for hand-shaking.

1-55. (canceled).

56. A method of controlling the exposure of a listener to narrow-band signals in an audio signal including the steps of:
periodically analysing the signal to determine the signal levels in particular frequency regions;
detecting a narrow-band signal based on whether the ratio of the signal level in a particular frequency region to the signal level in nearby higher and lower frequency regions exceeds a pre-determined threshold; and
in response to detection of a narrow-band signal, controlling the exposure of the listener to the detected narrow-band signal.

57. A method according to claim 56 wherein the periodic analyses of the signal are made at a frequency of about 125 Hz.

58. A method according to claim 56 wherein detection of a narrow-band signal is further based on whether the signal level in a particular frequency region exceeds a predetermined threshold.

59. A method according to claim 56 wherein detection of a narrow-band signal is further based on a comparison of the signal levels in particular frequency regions over a pre-determined number of periodic analyses.

60. A method according to claim 56 wherein detection of a narrow-band signal is further based on whether the frequency region in which the signal level exceeds the signal level in nearby higher and lower frequency regions does not change by more than a predetermined amount over a predetermined number of periodic analyses.

61. A method according to claim 59 wherein the predetermined number of periodic analyses is two.

62. A method according to claim 56 wherein the said nearby lower frequency region is not adjacent to the particular frequency region.

63. A method according to claim 62 wherein the said nearby lower frequency region lies within a range from 125 Hz to 375 Hz below the particular frequency region.

64. A method according to claim 56 wherein the said nearby higher frequency region is not adjacent to the particular frequency region.

65. A method according to claim 64 wherein the said nearby higher frequency region lies within a range from 125 Hz to 375 Hz above the particular frequency region.

66. A method according to claim 56 wherein the particular frequency regions lie within a range from 1 kHz to 4 kHz.

67. A method according to claim 56 further including the step of detecting additional narrow-band signals.

68. A method according to claim 67 wherein the audio signal is subdivided into a number of smaller frequency ranges and a narrow-band signal is detected in each of these ranges.

69. A method according to claim 67 wherein the frequency region of each identified narrow-band signal is stored to prevent those narrow-band signals from being detected again with the same periodic analysis.

70. A method according to claim 69 wherein the stored frequency regions are excluded from being used as the higher and lower frequency regions in the detection of narrow-band signals within the same periodic analysis.

71. A method according to claim 56 wherein the exposure of the listener is controlled by applying a filter to the signal, wherein the filter is arranged to attenuate the signal in the frequency range of a detected narrow-band signal.

72. A method according to claim 71 wherein the filter is applied for a predetermined time period.

73. A method according to claim 71 wherein the filter is applied by progressively increasing the degree of attenuation applied by the filter.

74. A method according to claim 71 wherein, following application of the filter, the degree of attenuation applied by the filter is progressively decreased.

75. A method according to claim 71 wherein the filter includes one or more band-reject filters having centre frequencies close to the centre frequency of the detected narrow-band signal.

76. A method according to claim 71 wherein the filter is an adaptive infinite impulse response filter.

77. A method according to claim 76 wherein each pole of the filter is paired with a zero located on the same radial axis on the z plane.

78. A method according to claim 76 wherein each pole of the filter has a fixed radius from the centre of the z plane and the radius of the zeros on the z-plane are progressively increased from the radial position of the poles towards the unit circle in proportion to the amount of attenuation specified.

79. A method according to claim 71 wherein a plurality of filters are applied to the audio signal.

80. A method according to claim 79 wherein the filters are applied in cascade.

81. A method according to claim 56 wherein the exposure of the listener is further controlled by attenuating the signal proportional to the amount by which its short-term level exceeds a given threshold.

82. A method according to claim 56 wherein the exposure of the listener is further controlled before the audio signal is reproduced by a transducer by being passed through a transducer specific filter being arranged to compensate for the frequency response of the transducer in combination with the ear to control the maximum sound pressure level presented to the ear of the listener.

83. A method according to claim 56 wherein the signal to which the listener is exposed is delayed relative to the analysis of the signal.

84. An apparatus for controlling the exposure of a listener to narrow-band signals in an audio signal including:
analysing means to periodically analyse the signal to determine the signal levels in particular frequency regions;
detection means arranged to detect a narrow-band signal based on whether the ratio of the signal level in a particular frequency region to the signal level in nearby higher and lower frequency regions exceeds a pre-determined threshold; and
controlling means arranged to control the exposure of the listener in response to detection of a narrow-band signal.

85. An apparatus according to claim 84 wherein the analysing means is arranged to make periodic analyses of the signal at a frequency of about 125 Hz.

86. An apparatus according to claim 84 wherein the detection means is arranged to detect a narrow-band signal further based on whether the signal level in a particular frequency region exceeds a predetermined threshold.

87. An apparatus according to claim 84 wherein the detection means is arranged to detect a narrow-band signal further based on a comparison of the signal levels in the particular frequency regions over a pre-determined number of periodic analyses.

88. An apparatus according to claim 84 wherein the detection means is arranged to detect a narrow-band signal further based on whether the frequency region in which the signal level exceeds the signal level in nearby higher and lower frequency regions does not change by more than a predetermined amount over a predetermined number of periodic analyses.

89. As apparatus according to claim 87 wherein the predetermined number of periodic analyses is two.

90. An apparatus according, to claim 84 wherein the said nearby lower frequency region is not adjacent to the particular frequency region.

91. An apparatus according to claim 90 wherein the said nearby lower frequency region lies within a range from 125 Hz to 375 Hz below the particular frequency region.

92. An apparatus according to claim 84 wherein the said nearby higher frequency region is not adjacent to the particular frequency region.

93. A method according to claim 92 wherein the said nearby higher frequency region lies within a range from 125 Hz to 375 Hz above the particular frequency region.

94. An apparatus according to claim 84 wherein the particular frequency regions lie within a range from 1 kHz to 4 kHz.

95. An apparatus according to claim 84 wherein the detection means is arranged to detect additional narrow-band signals.

96. An apparatus according to claim 95 wherein the analysing means is arranged to subdivide the audio signal into a number of smaller frequency ranges and the detection means is arranged to detect a narrow-band signal in each of these ranges.

97. An apparatus according to claim 95 further including storage means arranged to store the frequency region of each identified narrow-band signal.

98. An apparatus according to claim 84 wherein the controlling means includes a filter arranged to attenuate the signal in the frequency range of a detected narrow-band signal.

99. An apparatus according to claim 98 wherein the filter is arranged to be applied for a predetermined time period.

100. An apparatus according to claim 98 wherein the filter is arranged to be applied progressively increasing the degree of attenuation applied by the filter.

101. An apparatus according to claim 98 wherein, following application of the filter, the filter is arranged to progressively decrease the degree of attenuation applied by the filter.

102. An apparatus according to claim 98 wherein the filter includes one or more band-reject filters having centre frequencies close to the centre frequency of a detected narrow-band signal.

103. An apparatus according to claim 98 wherein the filter is an adaptive infinite impulse response filter.

104. An apparatus according to claim 103 wherein each pole of the filter is paired with a zero located on the same radial axis on the z plane.

105. An apparatus according to claim 103 wherein each pole of the filter has a fixed radius from the centre of the z plane and the radius of the zeros on the z-plane are progressively increased from the radial position of the poles towards the unit circle in proportion to the amount of attenuation specified.

106. An apparatus according to claim 98 including a plurality of filters which are arranged to be applied to the audio signal.

107. An apparatus according to claim 106 wherein the filters are arranged to be applied in cascade.

108. An apparatus according to claim 84 wherein the controlling means is further arranged to control the exposure of the listener by attenuating the signal proportional to the amount by which its short-term level exceeds a predefined threshold.

109. An apparatus to claim 84 wherein the controlling means is further arranged to control the exposure of the listener before the audio signal is reproduced by a transducer by passing the signal through a transducer specific filter being arranged to compensate for the frequency response of the transducer in combination with the ear to control the maximum sound pressure level presented to the ear of the listener.

110. An apparatus according to claim 84 further including delay means arranged to delay the signal so that the signal to which the listener is exposed is delayed relative to the analysis of the signal.
